(19) United States
(12) Patent Application Publication
(10) Pub. No.: US 2026/0188888 A1
(43) Pub. Date: Jul. 2, 2026

(54) ELECTRONIC DEVICE, CHIP PACKAGE STRUCTURE, AND PACKAGING CARRIER OF CHIP PACKAGE STRUCTURE

(71) Applicant: REALTEK SEMICONDUCTOR CORP., HSINCHU (TW)

(72) Inventor: Yu-Hsin Wang, HSINCHU (TW)

(21) Appl. No.: 19/404,228

(22) Filed: Dec. 1, 2025

(30) Foreign Application Priority Data
Dec. 27, 2024 (TW) 113151048

(51) Int. Cl. H01Q 1/22; H01Q 13/10; H10W 74/10

(52) U.S. Cl. CPC H01Q 1/2283; H01Q 13/10; H10W 74/111

(57) ABSTRACT

A packaging carrier includes an insulating layer and two metal layers embedded in the insulating layer. One of the two metal layers arranged adjacent to an outer surface of the insulating layer includes an antenna layout segment and a plurality of frequency adjustment pads. The antenna layout segment has a slot antenna recessed from an edge thereof and a plurality of layout holes that are located at two opposite sides of the slot antenna. The frequency adjustment pads are respectively located in the layout holes and are not in contact with the antenna layout segment. The frequency adjustment pads are exposed from the outer surface. The antenna layout segment has a plurality of slot-shape adjustment pads exposed from the outer surface. The slot-shape adjustment pads are arranged adjacent to a bottom of the slot antenna and are located at the two opposite sides of the slot antenna.

### CROSS-REFERENCE TO RELATED PATENT APPLICATION

This application claims the benefit of priority to Taiwan Patent Application No. 113151048, filed on December 27, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to an electronic device, a chip package structure, and a packaging carrier of a chip package structure.

### BACKGROUND OF THE DISCLOSURE

After an antenna is encapsulated in a conventional chip package structure through a manufacturing process or environment, the antenna is easily affected by the manufacturing processes or environment so as to have an issue associated with frequency offset. However, a frequency of the antenna encapsulated in the conventional chip package structure is difficult to adjust.

### SUMMARY OF THE DISCLOSURE

In response to the above-referenced technical inadequacies, the present disclosure provides an electronic device, a chip package structure, and a packaging carrier of a chip package structure for effectively improving on the issues associated with conventional chip package structures.

In order to solve the above-mentioned problems, one of the technical aspects adopted by the present disclosure is to provide an electronic device, which includes a chip package structure and a circuit board. The chip package structure includes a packaging carrier, an encapsulant, and an electronic chip. The packaging carrier defines a thickness direction and includes an insulating layer, an outside metal layer, and an inside metal layer. The insulating layer has an inner surface and an outer surface that is opposite to the inner surface. The outside metal layer is embedded in the insulating layer and is arranged adjacent to the outer surface. The outside metal layer includes an antenna layout segment and a plurality of frequency adjustment pads. The antenna layout segment has a slot antenna recessed from an edge thereof along a first direction perpendicular to the thickness direction. The slot antenna has a slot opening arranged on the edge, a bottom wall arranged away from the slot opening, and two lateral walls that are connected to the bottom wall. The antenna layout segment has a plurality of layout holes that are respectively located at two opposite sides of the slot antenna. The frequency adjustment pads are respectively arranged in the layout holes and are not in contact with the antenna layout segment. The frequency adjustment pads are exposed from the outer surface of the insulating layer. The antenna layout segment has a plurality of slot-shape adjustment pads that are exposed from the outer surface of the insulating layer. The slot-shape adjustment pads are arranged adjacent to the bottom wall and are respectively located at the two opposite sides of the slot antenna. The inside metal layer is embedded in the insulating layer and is arranged adjacent to the inner surface of the insulating layer. The encapsulant is formed on the inner surface of the insulating layer. The electronic chip is embedded in the encapsulant. The circuit board is configured to selectively provide at least one adjustment circuit. When the chip package structure is soldered onto the circuit board, the circuit board enables two of the slot-shape adjustment pads or two of the frequency adjustment pads to be electrically coupled to each other through the at least one adjustment circuit that is arranged across the slot antenna.

In order to solve the above-mentioned problems, another one of the technical aspects adopted by the present disclosure is to provide a chip package structure including a packaging carrier, an encapsulant, and an electronic chip. The packaging carrier defines a thickness direction and includes an insulating layer, an outside metal layer, and an inside metal layer. The insulating layer has an inner surface and an outer surface that is opposite to the inner surface. The outside metal layer is embedded in the insulating layer and is arranged adjacent to the outer surface. The outside metal layer includes an antenna layout segment and a plurality of frequency adjustment pads. The antenna layout segment has a slot antenna recessed from an edge thereof along a first direction perpendicular to the thickness direction. The slot antenna has a slot opening arranged on the edge, a bottom wall arranged away from the slot opening, and two lateral walls that are connected to the bottom wall. The antenna layout segment has a plurality of layout holes that are respectively located at two opposite sides of the slot antenna. The frequency adjustment pads are respectively arranged in the layout holes and are not in contact with the antenna layout segment. The frequency adjustment pads are exposed from the outer surface of the insulating layer. The antenna layout segment has a plurality of slot-shape adjustment pads that are exposed from the outer surface of the insulating layer. The slot-shape adjustment pads are arranged adjacent to the bottom wall and are respectively located at the two opposite sides of the slot antenna. The inside metal layer is embedded in the insulating layer and is arranged adjacent to the inner surface of the insulating layer. The encapsulant is formed on the inner surface of the insulating layer. The electronic chip is embedded in the encapsulant.

In order to solve the above-mentioned problems, yet another one of the technical aspects adopted by the present disclosure is to provide a packaging carrier includes an insulating layer, an outside metal layer, and an inside metal layer. The insulating layer has an inner surface and an outer surface that is opposite to the inner surface along a thickness direction. The outside metal layer is embedded in the insulating layer and is arranged adjacent to the outer surface. The outside metal layer includes an antenna layout segment and a plurality of frequency adjustment pads. The antenna layout segment has a slot antenna recessed from an edge thereof along a first direction perpendicular to the thickness direction. The slot antenna has a slot opening arranged on the edge, a bottom wall arranged away from the slot opening, and two lateral walls that are connected to the bottom wall. The antenna layout segment has a plurality of layout holes that are respectively located at two opposite sides of the slot antenna. The frequency adjustment pads are respectively arranged in the layout holes and are not in contact with the antenna layout segment. The frequency adjustment pads are exposed from the outer surface of the insulating layer. The antenna layout segment has a plurality of slot-shape adjustment pads that are exposed from the outer surface of the insulating layer. The slot-shape adjustment pads are arranged adjacent to the bottom wall and are respectively located at the two opposite sides of the slot antenna. The inside metal layer is embedded in the insulating layer and is arranged adjacent to the inner surface of the insulating layer.

Therefore, after the chip package structure provided by the present disclosure is manufactured, the circuit board can selectively provide the at least one adjustment circuit to compensate a frequency offset generated from the chip package structure (or the packaging carrier), thereby effectively providing higher antenna design flexibility and significantly reducing the design time of antenna.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an electronic device according to a first embodiment of the present disclosure;

FIG. 2 is a schematic perspective view showing a part of FIG. 1;

FIG. 3 is a schematic exploded view of FIG. 2;

FIG. 4 is a schematic exploded view showing an outside metal layer, an inside outer layer, and a matching component of FIG. 2;

FIG. 5 is a schematic top view of the outside metal layer of FIG. 4;

FIG. 6 is a schematic exploded view showing the outside metal layer, the inside outer layer, and the matching component of FIG. 2 in another configuration;

FIG. 7 is a schematic exploded view showing the outside metal layer, the inside outer layer, and the matching component of FIG. 2 in still another configuration;

FIG. 8 is a schematic top view of FIG. 2 when a substrate is omitted;

FIG. 9 is a schematic top view showing a first variation of the configuration shown in FIG. 8;

FIG. 10 is a schematic top view showing a second variation of the configuration shown in FIG. 8;

FIG. 11 is a schematic top view showing a third variation of the configuration shown in FIG. 8;

FIG. 12 is a schematic graph showing a radiation efficiency of the electronic device in different configurations compared to a radiation efficiency of the electronic device provided without any adjustment circuit according to the first embodiment of the present disclosure;

FIG. 13 is a schematic graph showing a return loss of the electronic device in different configurations compared to a return loss of the electronic device provided without any adjustment circuit according to the first embodiment of the present disclosure;

FIG. 14 is a schematic top view showing a fourth variation of the configuration shown in FIG. 8;

FIG. 15 is a schematic top view showing a fifth variation of the configuration shown in FIG. 8;

FIG. 16 is a schematic perspective view showing a part of the electronic device according to a second embodiment of the present disclosure;

FIG. 17 is a schematic exploded view of FIG. 16; and

FIG. 18 is a schematic exploded view showing the outside metal layer, the inside outer layer, an expansion metal layer, and the matching component of FIG. 16.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

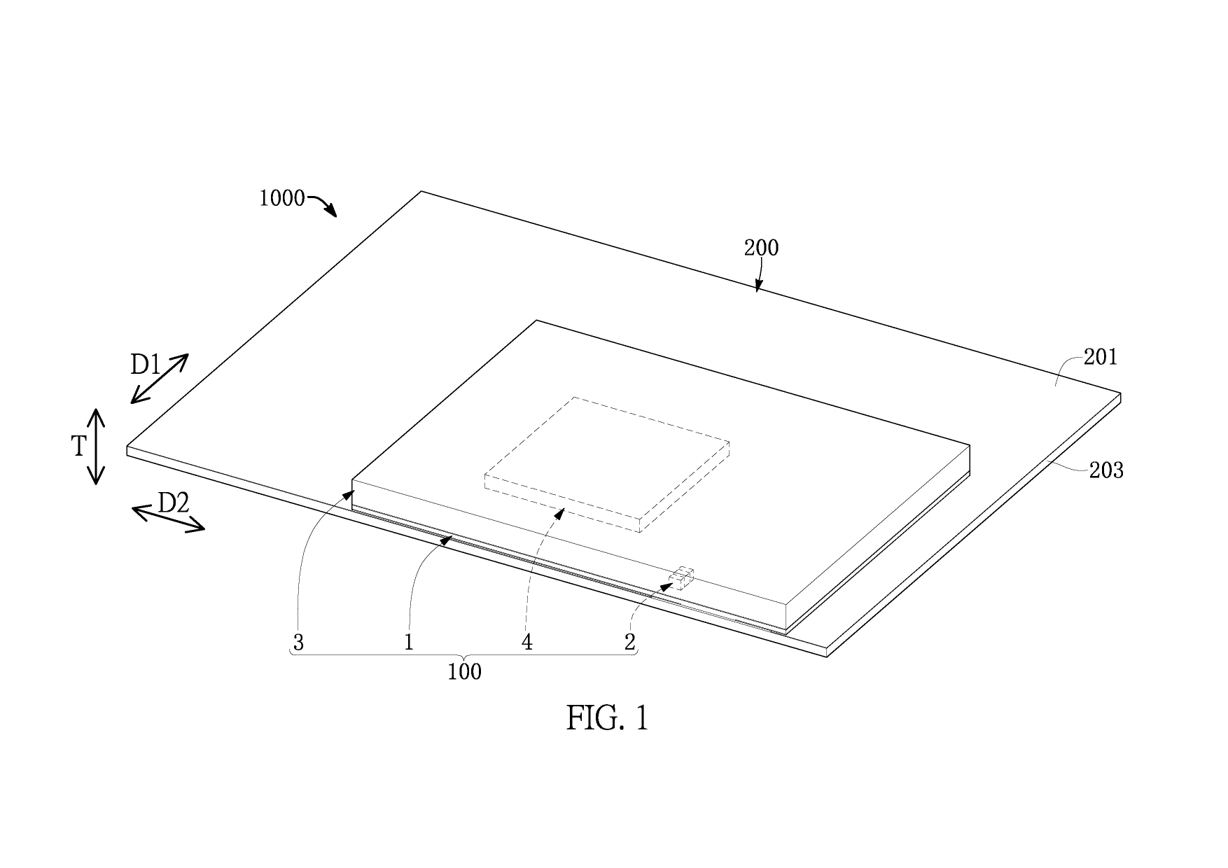

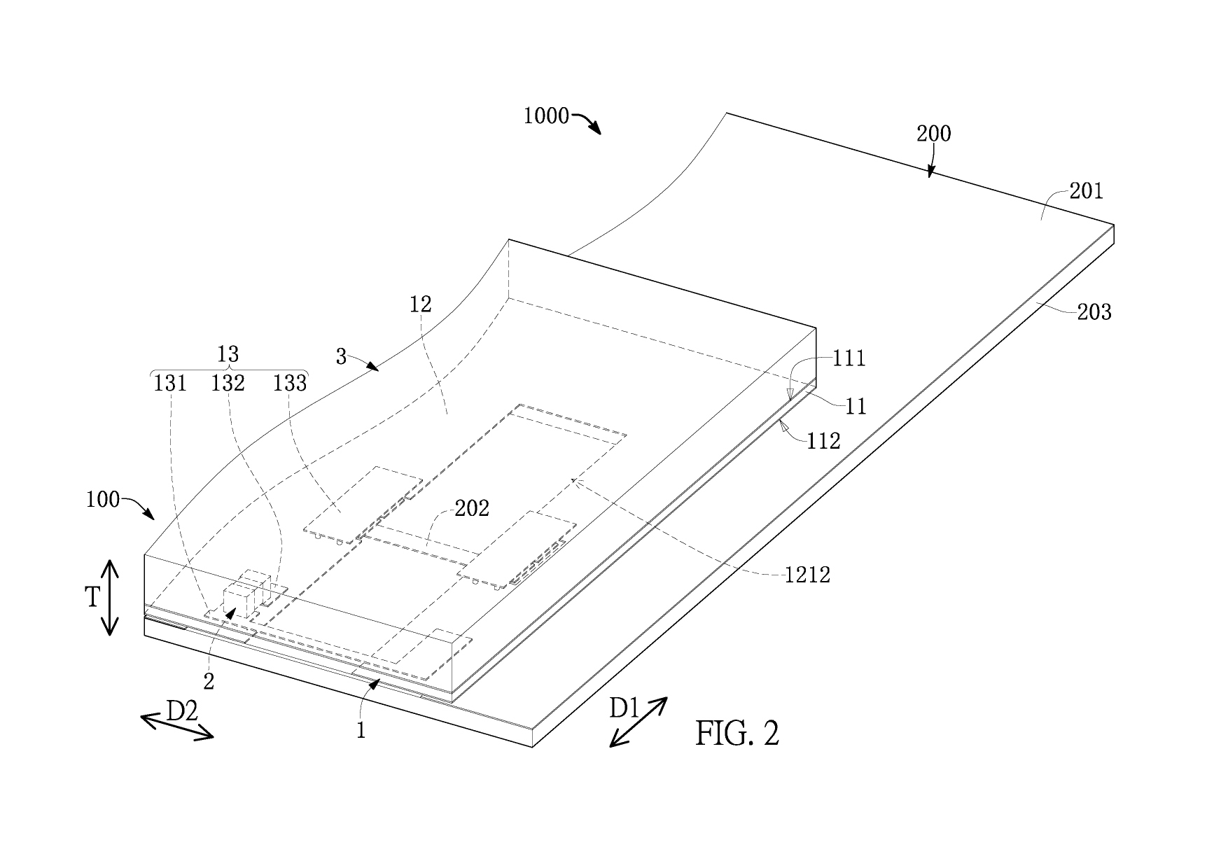

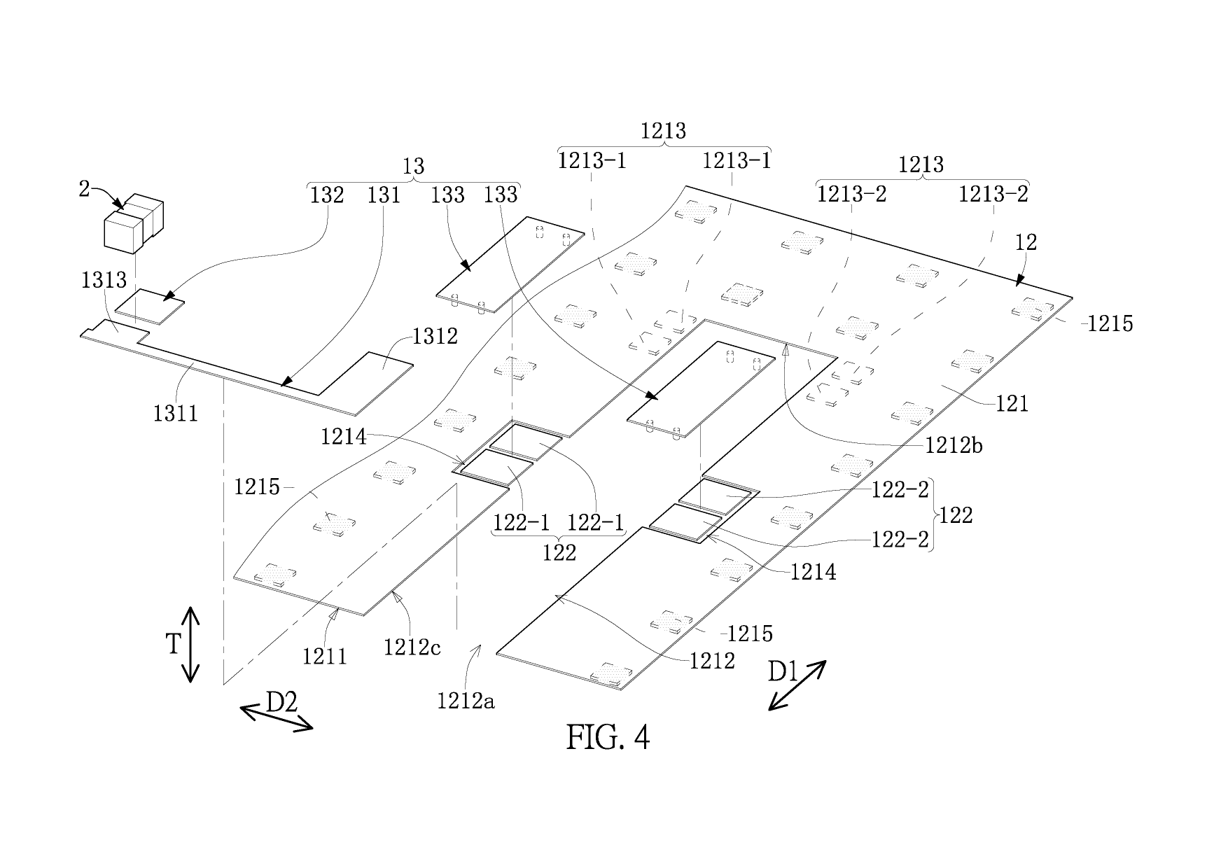

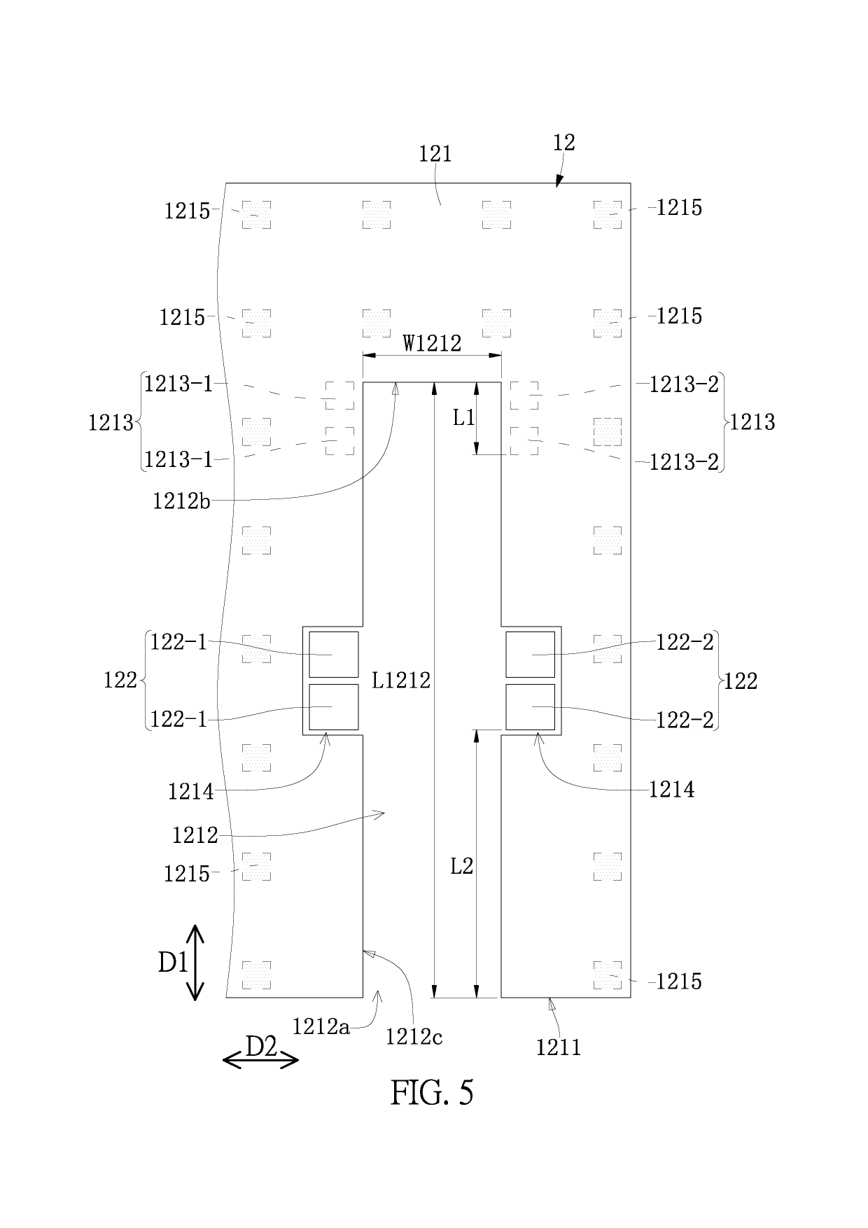

Referring to FIG. 1 to FIG. 15, a first embodiment of the present disclosure is provided. As shown in FIG. 1 to FIG. 3, the present embodiment provides an electronic device 1000, which includes a chip package structure 100 and a circuit board 200 that is provided for allowing the chip package structure 100 to be soldered thereon. It should be noted that the chip package structure 100 in the present embodiment is described in cooperation with the circuit board 200, but the present disclosure is not limited thereto. For example, in other embodiments of the present disclosure not shown in the drawings, the chip package structure 100 can be independently used (e.g., sold) or can be used in cooperation with other components.

The chip package structure 100 in the present embodiment includes a packaging carrier 1, a matching component 2 assembled to the packaging carrier 1, an encapsulant 3 formed on the packaging carrier 1, and an electronic chip 4 that is embedded in the encapsulant 3. An interior of the packaging carrier 1 is provided with an antenna function, and the following description mainly describes a partial structure of the packaging carrier 1 corresponding to the antenna function. However, other structures of the packaging carrier 1 corresponding to the electronic chip 4 can be adjusted or changed according to practical requirements, and the present disclosure is not limited thereto. In order to clearly describe the present embodiment, the packaging carrier 1 defines a thickness direction T, a first direction D1 perpendicular to the thickness direction T, and a second direction D2 that is perpendicular to the thickness direction T and the first direction D1.

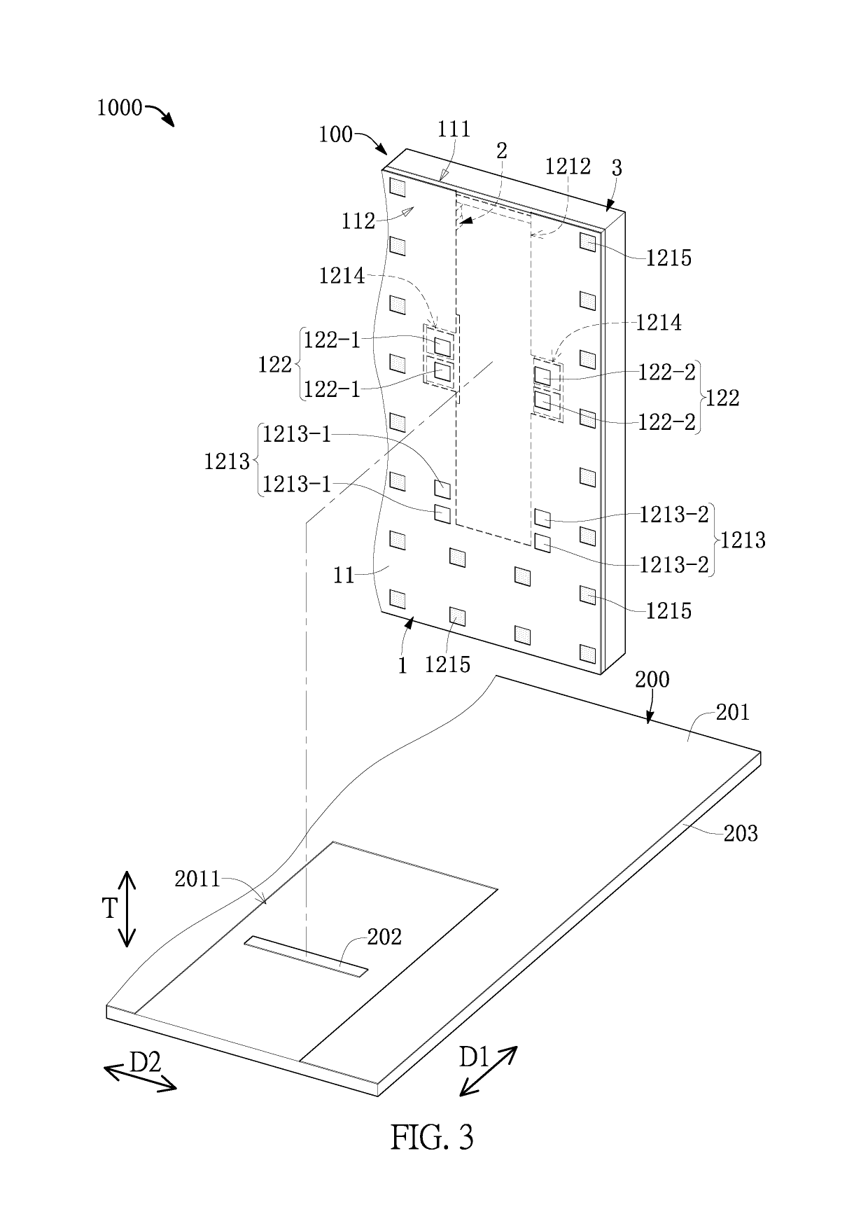

As shown in FIG. 3 to FIG. 5, the packaging carrier 1 in the present embodiment can also be regarded as a packaging substrate 1 and includes an insulating layer 11, an outside metal layer 12 embedded in the insulating layer 11, and an inside metal layer 13 that is embedded in the insulating layer 11. The insulating layer 11 has an inner surface 111 and an outer surface 112 that is opposite to the inner surface 111. The insulating layer 11 can be made by laminating a plurality of insulating materials to form a single one-piece structure and two solder mask layers that are respectively formed on two outer sides of the insulating materials. Each of the insulating materials has a thickness that can be within a range from 20 μm to 100 μm, but the present disclosure is not limited thereto.

Moreover, the outside metal layer 12 and the inside metal layer 13 in the present embodiment each have a thickness being within a range from 10 μm to 30 μm, and are spaced apart from each other along the thickness direction T. the outside metal layer 12 is arranged adjacent to the outer surface 112, and the inside metal layer 13 is arranged adjacent to the inner surface 111.

Specifically, the outside metal layer 12 includes an antenna layout segment 121 and a plurality of frequency adjustment pads 122 that are arranged corresponding to the antenna layout segment 121. The antenna layout segment 121 has a slot antenna 1212 recessed from an edge 1211 thereof along the first direction D1. The slot antenna 1212 has a slot opening 1212a arranged on the edge 1211, a bottom wall 1212b arranged away from the slot opening 1212a, and two lateral walls 1212c that are (perpendicularly) connected to the bottom wall 1212b.

In the present embodiment, the slot antenna 1212 has a slot depth L1212 along the first direction D1 and a slot width W1212 along the second direction D2. In other words, the slot depth L1212 is a distance between the slot opening 1212a and the bottom wall 1212b and is preferably within a range from 6.5 mm to 7 mm, and the slot width W1212 is a distance between the two lateral walls 1212c and is preferably within a range from 1 mm to 1.5 mm, but the present disclosure is not limited thereto.

Moreover, the antenna layout segment 121 has a plurality of slot-shape adjustment pads 1213 exposed from the outer surface 112 of the insulating layer 11. The slot-shape adjustment pads 1213 are arranged adjacent to the bottom wall 1212b and are respectively located at two opposite sides of the slot antenna 1212. Furthermore, the slot-shape adjustment pads 1213 and the bottom wall 1212 have a maximum separation distance L1 therebetween that is preferably less than or equal to 30% of the slot depth L1212, but the present disclosure is not limited thereto.

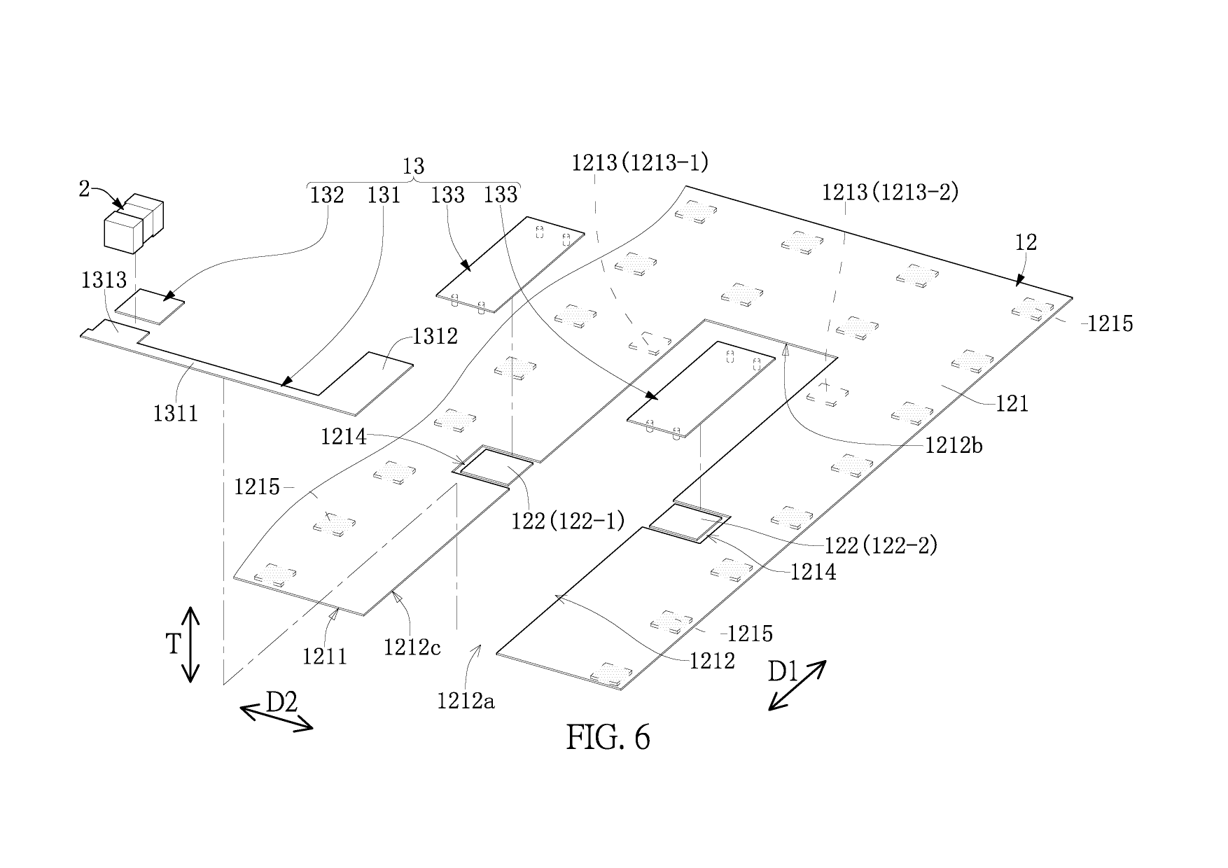

In other words, the slot-shape adjustment pads 1213 are respectively arranged adjacent to the two lateral walls 1212c and are not in contact with the two lateral walls 1212c. In the present embodiment, a quantity of the slot-shape adjustment pads 1213 arranged adjacent to any one of the two lateral walls 1212c is two and can be adjusted or changed according to practical requirements. For example, as shown in FIG. 6, a quantity of the slot-shape adjustment pads 1213 arranged adjacent to any one of the two lateral walls 1212c can be just one; or, in other embodiments of the present disclosure not shown in the drawings, a quantity of the slot-shape adjustment pads 1213 can be adjusted according to practical requirements.

In addition, the antenna layout segment 121 has a plurality of layout holes 1214 that are respectively located at two opposite sides of the slot antenna 1212. The layout holes 1214 are respectively recessed in the two lateral walls 1212c of the slot antenna 1212. In other words, each of the layout holes 1214 is in spatial communication with an inner region surrounded by the slot antenna 1212.

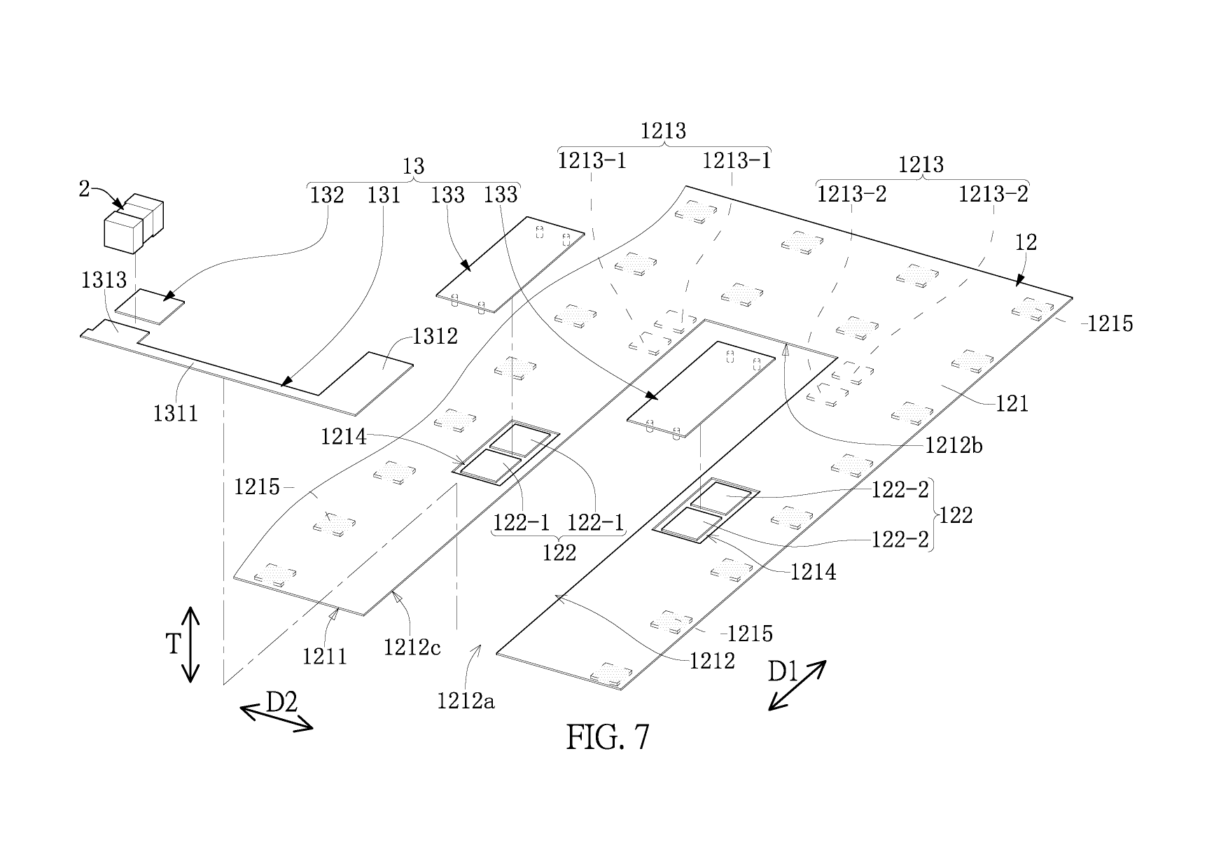

Moreover, a quantity of the layout holes 1214 in the present embodiment is two, and the two layout holes 1214 face toward each other along the second direction D2, but the present disclosure is not limited thereto. For example, as shown in FIG. 7, the layout holes 1214 can be arranged adjacent to the two lateral walls 1212c, but are not in contact with the two lateral walls 1212c. In other words, each of the layout holes 1214 is not in spatial communication with the inner region surrounded by the slot antenna 1212. Or, in other embodiments of the present disclosure not shown in the drawings, the layout holes 1214 can be in a staggered arrangement.

The frequency adjustment pads 122 are respectively arranged in the layout holes 1213 and are not in contact with the antenna layout segment 121, and the frequency adjustment pads 122 are exposed from the outer surface 112 of the insulating layer 11. In the present embodiment, each of the layout holes 1213 is provided with two of the frequency adjustment pads 122 therein that are arranged adjacent to and spaced apart from each other, each of the frequency adjustment pads 122 does not protrude from a corresponding one of the two lateral walls 1212c of the slot antenna 1212, and each of the frequency adjustment pads 122 is partially exposed from the outer surface 112, but the present disclosure is not limited thereto.

Moreover, the frequency adjustment pads 122 are respectively located at the two opposite sides of the slot antenna 1212, and the frequency adjustment pads 122 are further away from the bottom wall 1212b than the slot-shape adjustment pads 1213. In the present embodiment, the frequency adjustment pads 122 and the slot-shape adjustment pads 1213 are substantially arranged in two rows along the two lateral walls 1212c.

Specifically, the frequency adjustment pads 122 and the slot opening 1212a (or the edge 1211) have an arrangement distance L2 therebetween that is greater than or equal to 30% of the slot depth L1212.

In addition, the outside metal layer 12 has a plurality of grounding pads 1215 exposed from the outer surface 112 of the insulating layer 11, and the grounding pads 1215 are arranged around (or surround) an outer side of the antenna layout segment 121, thereby forming a complete ground loop. In the present embodiment, the grounding pads 1215 are substantially in a U-shaped arrangement and surround the frequency adjustment pads 122 and the slot-shape adjustment pads 1213, and a quantity of the grounding pads 1215 is greater than a sum of a quantity of the frequency adjustment pads 122 and a quantity of the slot-shape adjustment pads 1213, but the present disclosure is not limited thereto. For example, in other embodiments of the present disclosure not shown in the drawings, a quantity of the slot-shape adjustment pads 1213 can be adjusted according to practical requirements.

The inner region surrounded by the slot antenna 1212 defines an extension space along the thickness direction T, and the inside metal layer 13 includes a feeding circuit 131 arranged across the extending space, a metal pad 132 that is located at one side of the extending space, and two coupling segments 133 that are located at two opposite sides of the extending space. The feeding circuit 131 is arranged adjacent to the slot opening 1212a of the slot antenna 1212, the metal pad 132 is configured for being grounded, and the metal pad 132 is spaced apart from and arranged adjacent to one end of the feeding circuit 131.

Specifically, the feeding circuit 131 in the present embodiment includes a bridging segment 1311, a first extension segment 1312 connected to one end of the bridging segment 1311, and a second extension segment 1313 that is connected to another end of the bridging segment 1311. The bridging segment 1311 is an elongated structure parallel to the second direction D2 and is arranged adjacent to the slot opening 1212a (or the edge 1211). The first extension segment 1312 extends from the bridging segment 1311 in a direction away from the slot opening 1212a, and has a length along the first direction D1 and a width along the second direction D2. The length of the first extension segment 1312 is within a range from 0.6 mm to 1 mm, and the width of the first extension segment 1313 is within a range from 0.4 mm to 0.5 mm. Furthermore, the second extension segment 1313 extends from the bridging segment 1311 in a direction away from the slot opening 1212a, the metal pad 132 is arranged adjacent to and spaced apart from the second extension segment 1313, and the second extension segment 1313 and the metal pad 132 face toward the first extension segment 1312 along the second direction D2.

The two coupling segments 133 are electrically coupled to the antenna layout segment 121, and the two coupling segments 133 are respectively spaced apart from the first extension segment 1312 of the feeding circuit 131 and the metal pad 132. The two coupling segments 133 shield (or are overlapped with) the layout holes 1213 and the frequency adjustment pads 122 along the thickness direction T. It should be noted that the packaging carrier 1 in the present embodiment is preferably provided without any metal layer between the outside metal layer 12 and the inside metal layer 13, thereby enabling the frequency adjustment pads 122 to electrically couple to the two coupling segments 133, but the present disclosure is not limited thereto.

The matching component 2 is connected to the feeding circuit 131 and the metal pad 132, and the matching component 2 in the present embodiment is a capacitor having a capacitance value within a range from 2.5 pF to 4 pF, but the present disclosure is not limited thereto. For example, in other embodiments of the present disclosure not shown in the drawings, the matching component 2 can be omitted or can be replaced by other components according to practical requirements.

The electronic chip 4 is assembled to the packaging carrier 1 and is arranged on the inner surface 111 of the insulating layer 11, and the electronic chip 4 is electrically coupled to the feeding circuit 131 of the inside metal layer 13 through the packaging carrier 1. Moreover, the encapsulant 3 is formed on the inner surface 111 of the insulating layer 11, and the electronic chip 4 and the matching component 2 are embedded in the encapsulant 3. In the present embodiment, a surrounding lateral side of the encapsulant 3 is flush with an outer edge of the packaging carrier 1.

It should be noted that the packaging carrier 1 in the present embodiment is described in cooperation with the encapsulant 3 and the matching component 2, but the present disclosure is not limited thereto. For example, in other embodiments of the present disclosure not shown in the drawings, the packaging carrier 1 can be independently used (e.g., sold) or can be used in cooperation with other components.

The above description describes the structure of the packaging carrier 1 provided by the present embodiment, and the slot antenna 1212 of the chip package structure 100 has an initial center frequency. The following description describes a structural cooperation between the packaging carrier 1 and the circuit board 200, and the electronic device 1000 defines a predetermined center frequency. The chip package structure 100 is soldered onto the circuit board 200 through the packaging carrier 1, such that the electronic chip 4 can be electrically coupled to the circuit board 200 through the packaging carrier 1.

Specifically, the circuit board 200 includes a substrate 203 and a grounding layer 201 that is formed on the substrate 203 and that is electrically coupled to the grounding pads 1215. The grounding layer 201 has a clearance hole 2011. Moreover, the circuit board 200 includes at least one adjustment circuit 202 formed on the substrate 203, and the at least one adjustment circuit 202 is arranged in the clearance hole 2011 and is not in contact with the grounding layer 201. The grounding pads 1215 are arranged outside of (or surround) the clearance hole 2011, and a projection region defined by orthogonally projecting the slot antenna 1212 onto the grounding layer 201 along the thickness direction T is located in the clearance hole 2011.

In summary, when the chip package structure 100 is soldered onto the circuit board 200, the circuit board 200 enables two of the slot-shape adjustment pads 1213 or two of the frequency adjustment pads 122 to be electrically coupled to each other through the at least one adjustment circuit 202 that is arranged across the slot antenna 1212. Accordingly, after the chip package structure 100 is manufactured, the circuit board 200 can selectively provide the at least one adjustment circuit 202 to compensate a frequency offset generated from the chip package structure 100 (or the packaging carrier 1), thereby effectively providing higher antenna design flexibility and significantly reducing the design time of antenna.

In other words, the chip package structure 100 of the present embodiment can provide a frequency adjustment function in a scaled manner, and the initial center frequency of the chip package structure 100 is able to be adjusted to the predetermined center frequency by being connected to the at least one adjustment circuit 202. It should be noted that, when the initial center frequency of the chip package structure 100 is different from the predetermined center frequency by the frequency offset, the circuit board 200 can compensate or eliminate the frequency offset by being formed with the at least one adjustment circuit 202. In other words, if the initial center frequency of the chip package structure 100 is substantially equal to the predetermined center frequency, the circuit board 200 can be provided without the at least one adjustment circuit 202. In other words, a quantity of the at least one adjustment circuit 202 formed on the circuit board 200 can be zero. Accordingly, the circuit board 200 in the present embodiment is configured to selectively provide the at least one adjustment circuit 202.

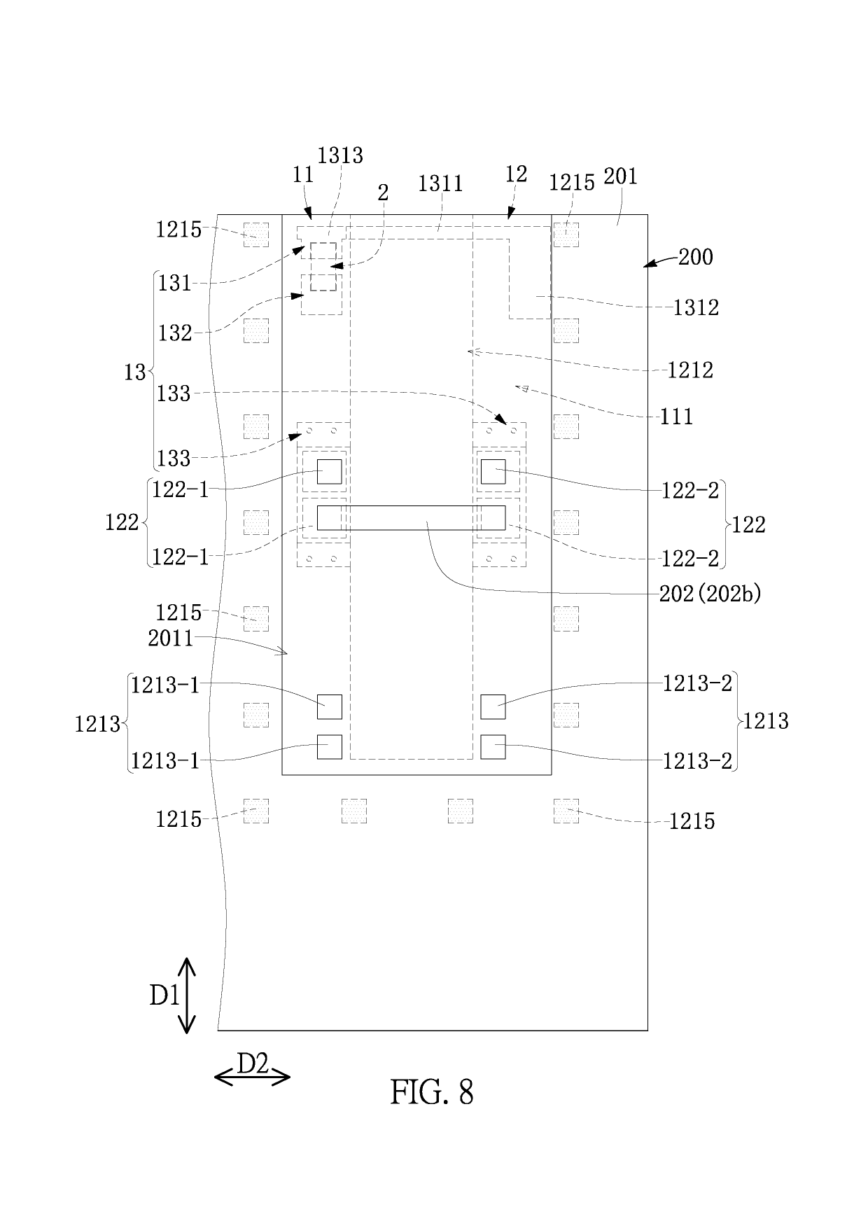

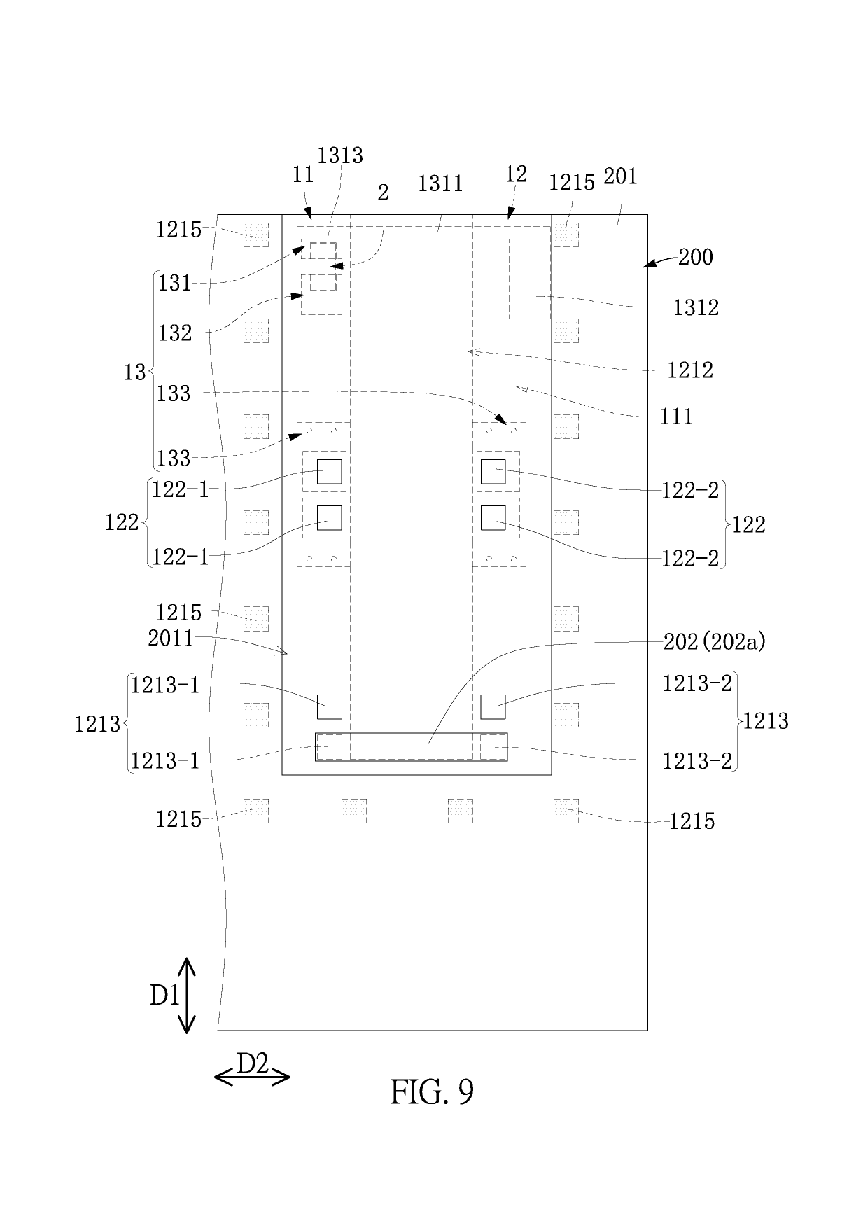

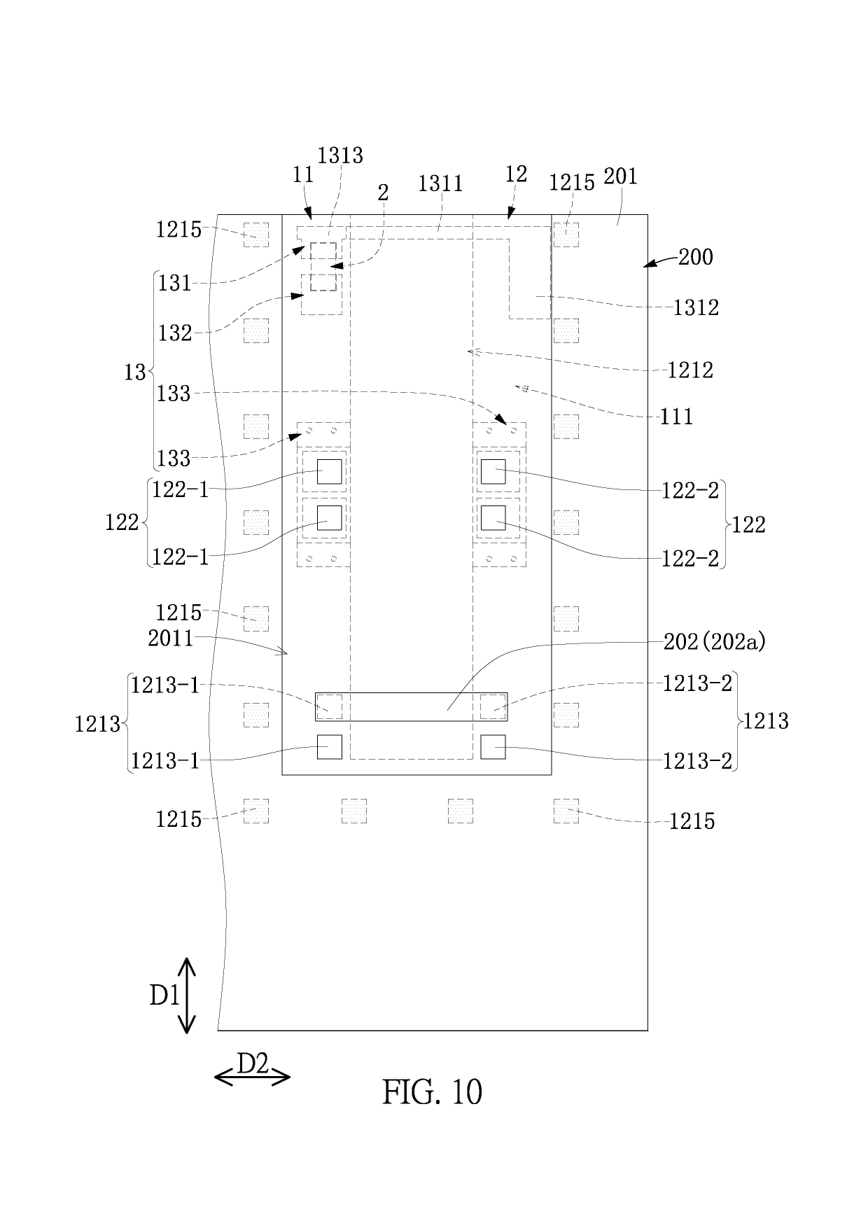

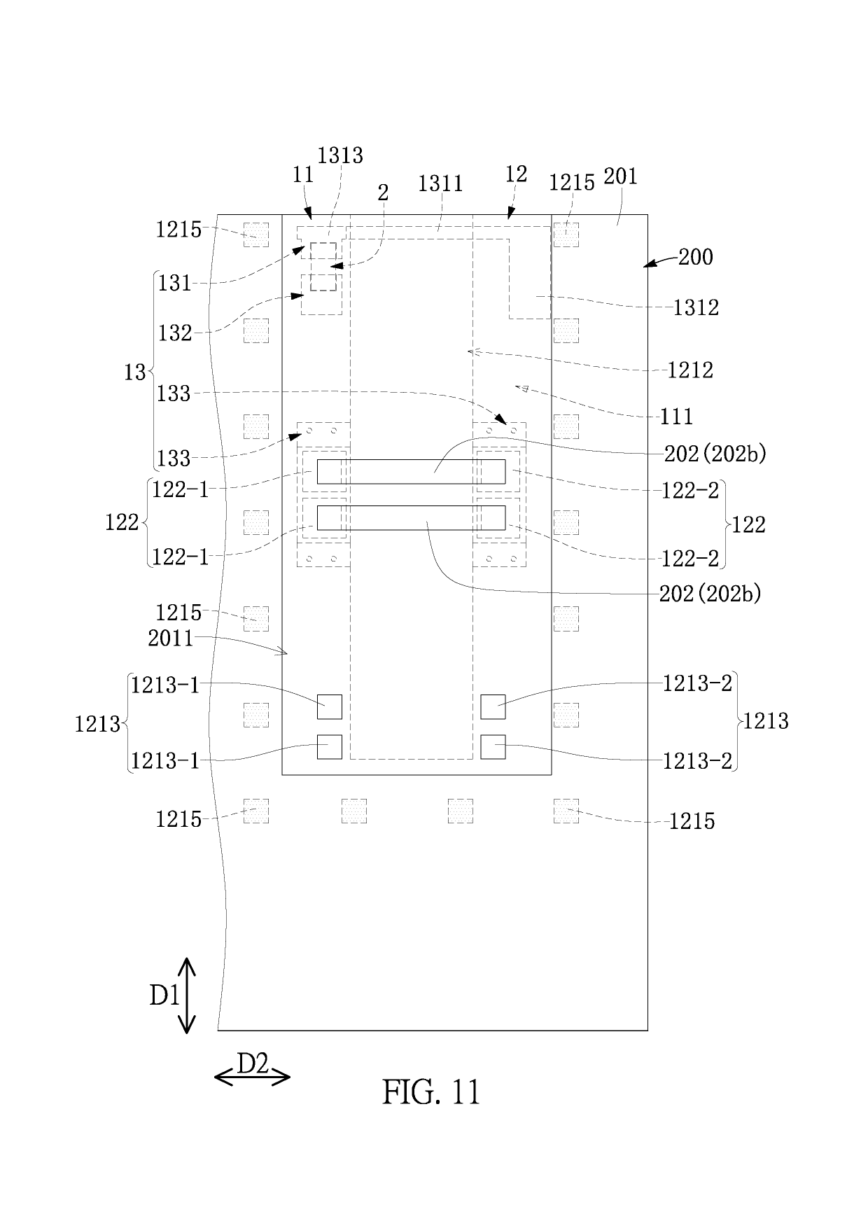

Specifically, the circuit board 200 can use the at least one adjustment circuit 202 to connect two of the slot-shape adjustment pads 1213 (as shown in FIG. 9 and FIG. 10) or two of the frequency adjustment pads 122 (as shown in FIG. 8 and FIG. 11) according to practical conditions, thereby achieving the frequency adjustment effect. In other words, the slot-shape adjustment pads 1213 and the frequency adjustment pads 122 in the present embodiment can provide the frequency adjustment function through the at least one adjustment circuit 202, and the cooperation of the slot-shape adjustment pads 1213, the frequency adjustment pads 122, and the at least one adjustment circuit 202 can be adjusted according to practical requirements and is not limited by the drawings of the present disclosure.

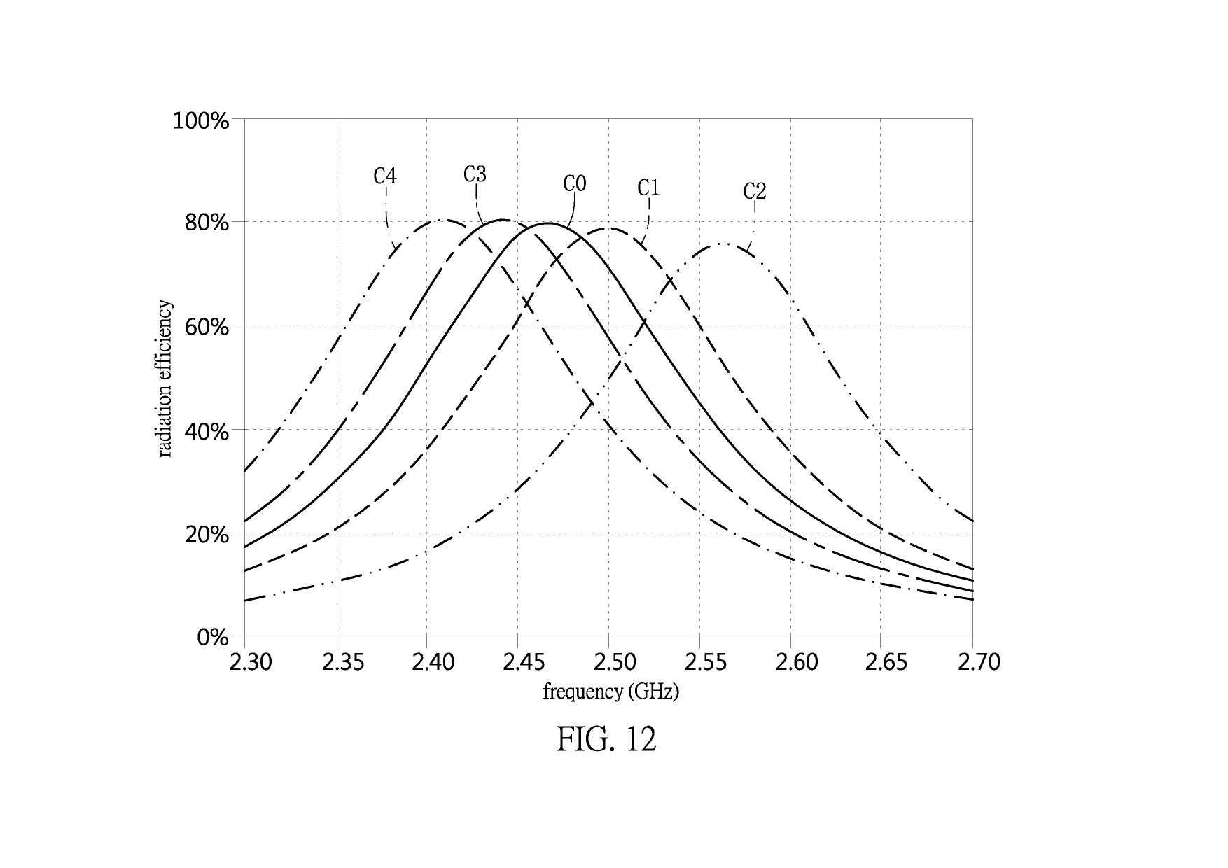

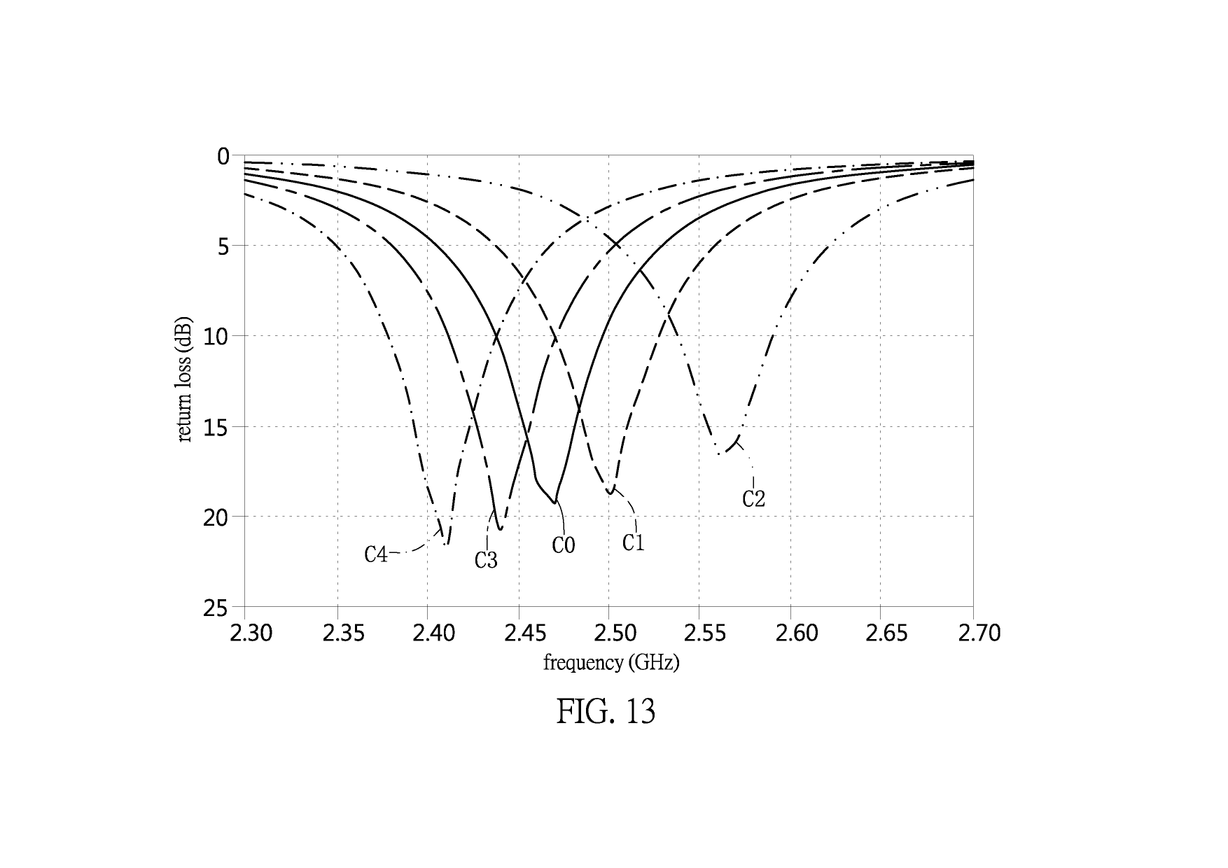

Furthermore, in a radiation efficiency graph shown in FIG. 12 and a return loss graph shown in FIG. 13 that are obtained by simulation experiments, a curve line C0 represents (or is obtained from) the circuit board 200 of the electronic device 1000 provided without any adjustment circuit 202, a curve line C1 represents the circuit board 200 shown in FIG. 9, a curve line C2 represents the circuit board 200 shown in FIG. 10, a curve line C3 represents the circuit board 200 shown in FIG. 8, and a curve line C4 represents the circuit board 200 shown in FIG. 11. According to FIG. 12 and FIG. 13, in the electronic device 1000 provided by the present embodiment, the initial center frequency of the chip package structure 100 can be effectively adjusted through the cooperation of the chip package structure 100 and the at least one adjustment circuit 202, and a range of the frequency adjustment can be at least 150 MHz for meeting different wireless communication protocols (e.g., Bluetooth protocol).

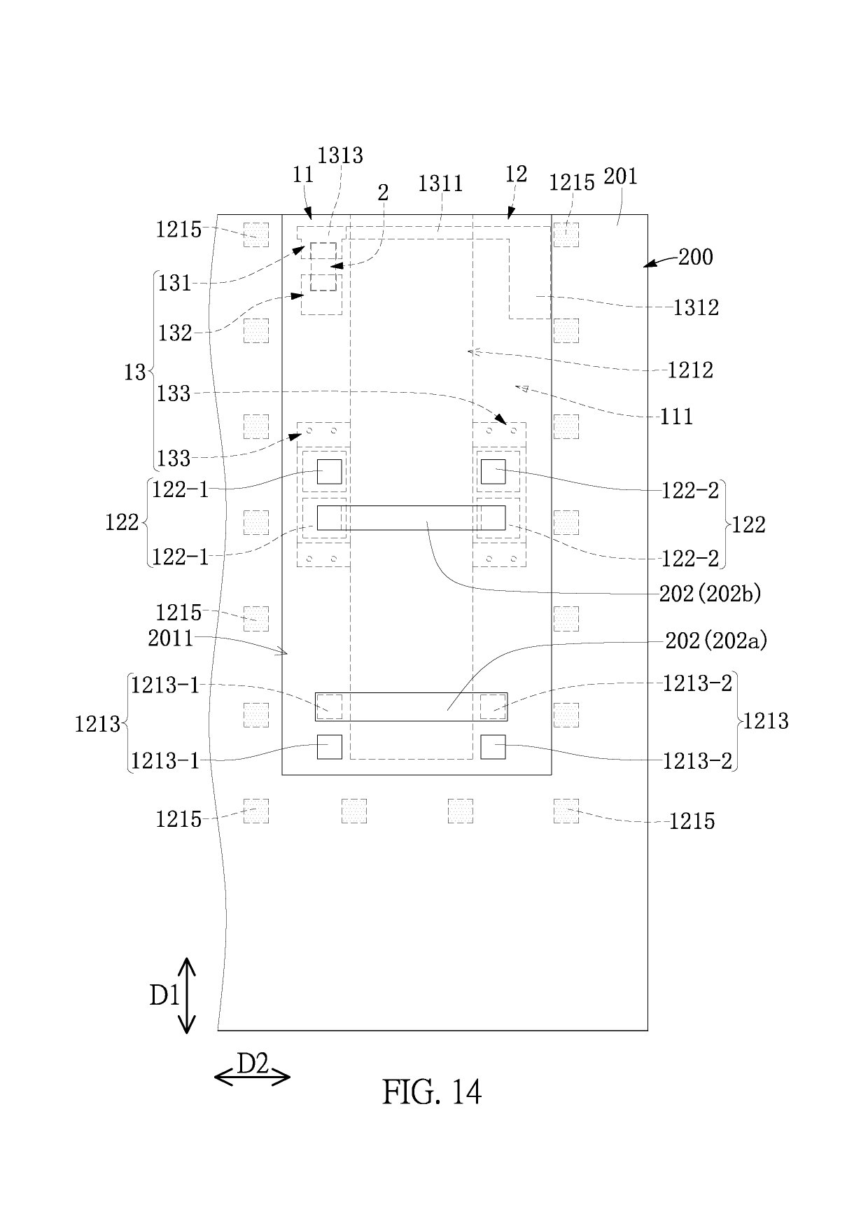

Moreover, a quantity of the at least one adjustment circuit 202 formed on the circuit board 200 can be adjusted to be more than one (e.g., two) according to practical requirements. For example, as shown in FIG. 14, one of the adjustment circuits 202 connects two of the slot-shape adjustment pads 1213 and is defined as a slot-shape adjustment circuit 202a, and another one of the adjustment circuits 202 connects two of the frequency adjustment pads 122 and is defined as a frequency adjustment circuit 202b.

In order to clearly describe the present embodiment, the following description further describes the slot-shape adjustment pads 1213 and the frequency adjustment pads 122. In the present embodiment, the slot-shape adjustment pads 1213 include a plurality of first slot-shape adjustment pads 1213-1 that are located at one of the two opposite sides of the slot antenna 1212 and a plurality of second slot-shape adjustment pads 1213-2 that are located at another one of the two opposite sides of the slot antenna 1212. Each of the first slot-shape adjustment pads 1213-1 is allowed to be electrically coupled to any one of the second slot-shape adjustment pads 1213-2 through the slot-shape adjustment circuit 202a, such that a bottom of the slot antenna 1212 can be changed from the bottom wall 1212b to the slot-shape adjustment circuit 202a for adjusting the initial center frequency.

Moreover, the frequency adjustment pads 122 include a plurality of first frequency adjustment pads 122-1 that are located at one of the two opposite sides of the slot antenna 1212 and a plurality of second frequency adjustment pads 122-2 that are located at another one of the two opposite sides of the slot antenna 1212. Each of the first frequency adjustment pads 122-1 is allowed to be electrically coupled to any one of the second frequency adjustment pads 122-2 through the frequency adjustment circuit 202b for providing a capacitive effect and changing the initial center frequency.

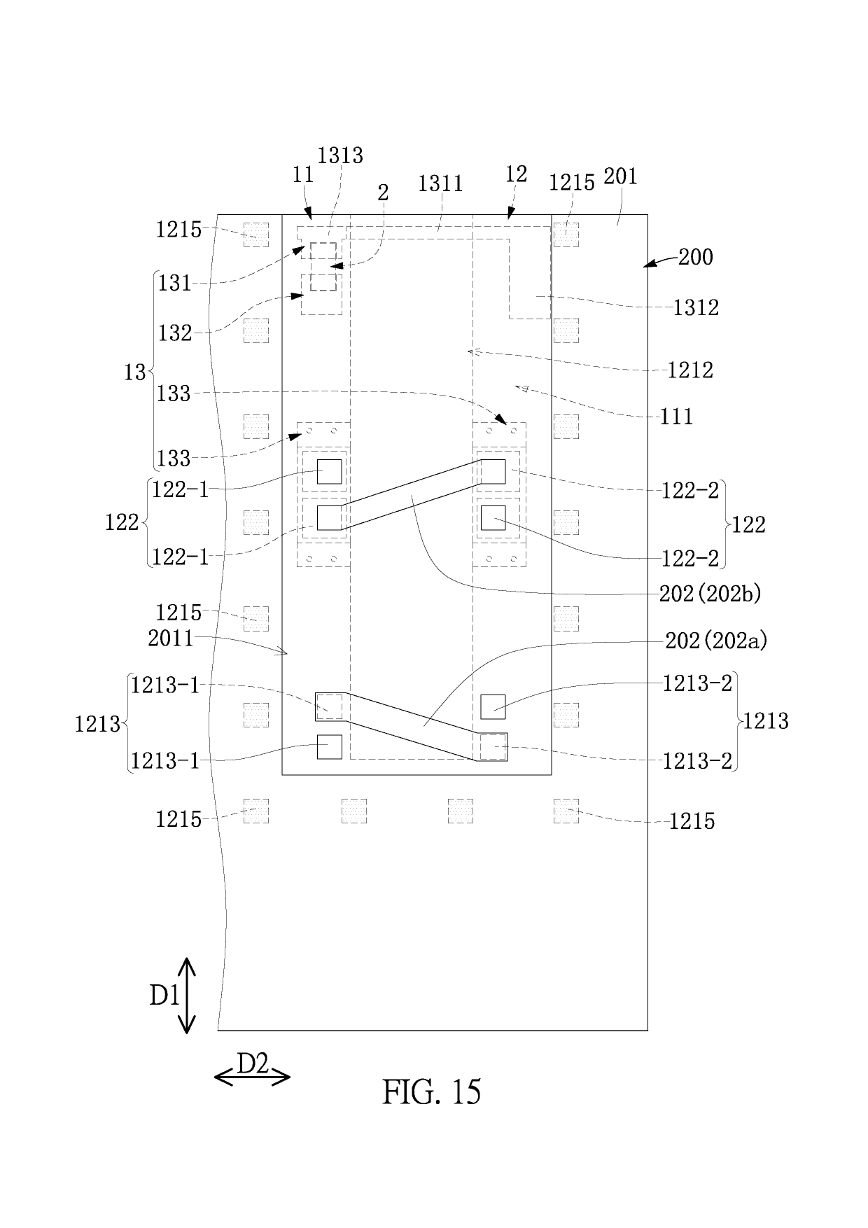

Specifically, each of the first slot-shape adjustment pads 1213-1 faces toward one of the second slot-shape adjustment pads 1213-2 along the second direction D2, each of the first frequency adjustment pads 122-1 faces toward one of the second frequency adjustment pads 122-2 along the second direction D2, and the slot-shape adjustment circuit 202a and the frequency adjustment circuit 202b are parallel to the second direction D2, but the present disclosure is not limited thereto. For example, as shown in FIG. 15, any one of the slot-shape adjustment circuit 202a and the frequency adjustment circuit 202b can be not parallel to the second direction D2.

### Second Embodiment

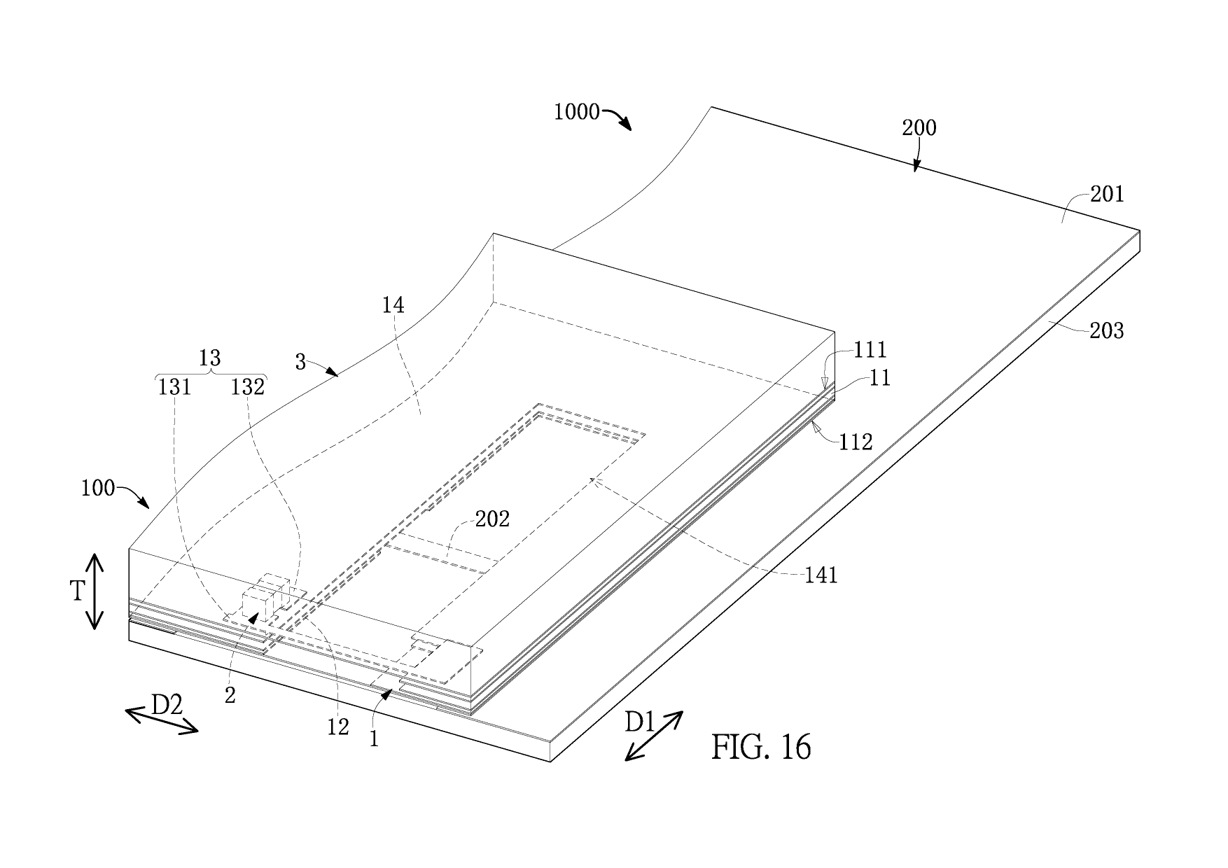

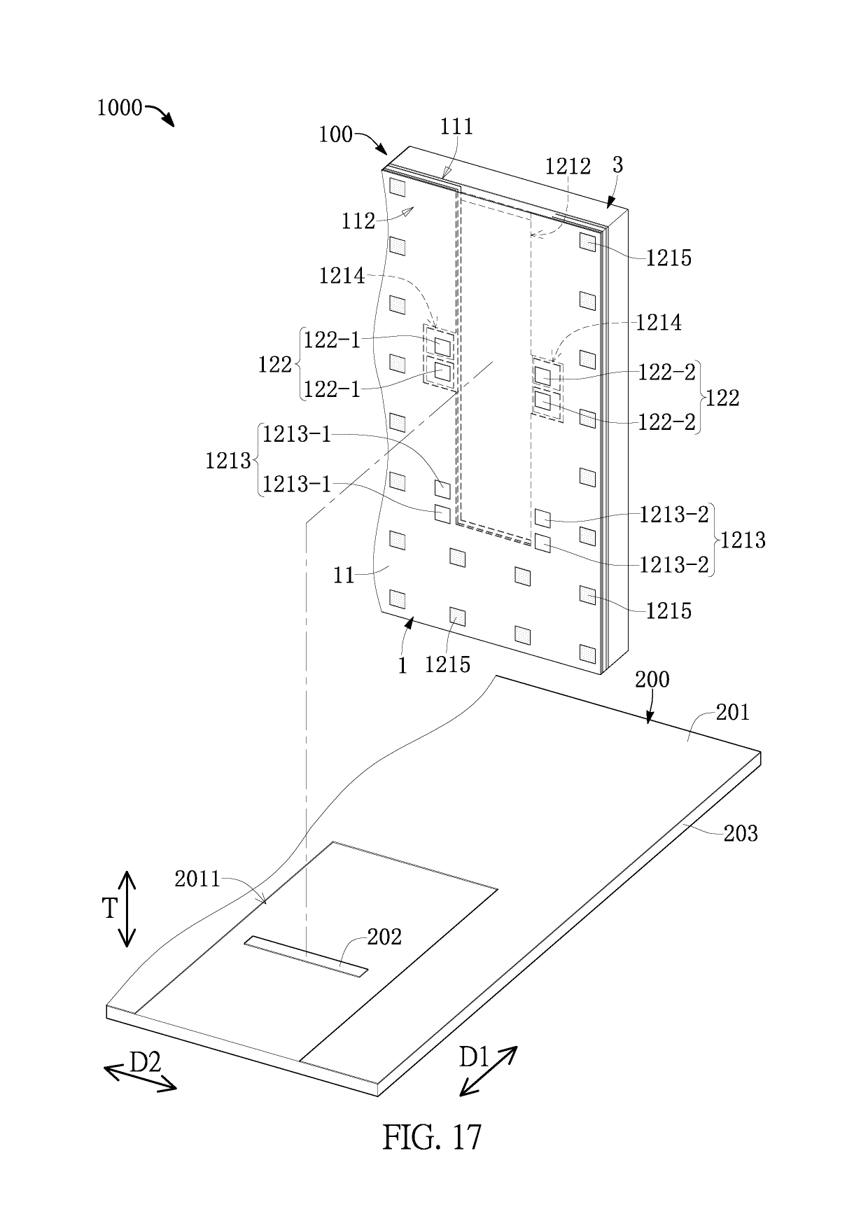

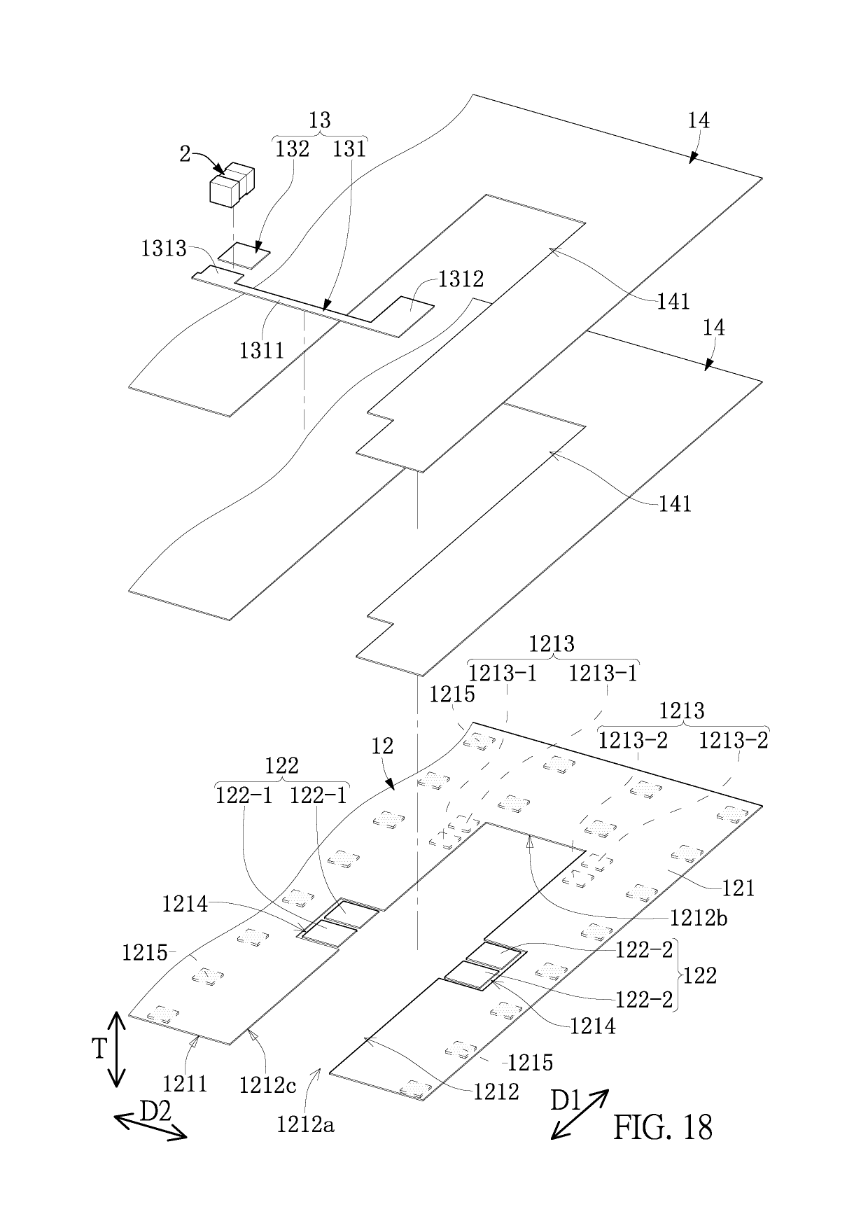

Referring to FIG. 16 to FIG. 18, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the inside metal layer 13 of the packaging carrier 1 is provided without the two coupling segments 133, and the packaging carrier 1 further includes at least one expansion metal layer 14 that is embedded in the insulating layer 11 and that is arranged between the inside metal layer 13 and the outside metal layer 12. The at least one expansion metal layer 14 shields the layout holes 1214 and the frequency adjustment pads 122 along the thickness direction T.

Moreover, the at least one expansion metal layer 14 has a coupling slot 141, and at least 80% of an inner wall of the coupling slot 141 is overlapped with the bottom wall 1212b and the two lateral walls 1212c of the slot antenna 1212 along the thickness direction T. In addition, a quantity of the at least one expansion metal layer 14 in the present embodiment is two, but the present disclosure is not limited thereto.

### Beneficial Effects of the Embodiments

In conclusion, after the chip package structure provided by the present disclosure is manufactured, the circuit board can selectively provide the at least one adjustment circuit to compensate a frequency offset generated from the chip package structure (or the packaging carrier), thereby effectively providing higher antenna design flexibility and significantly reducing the design time of antenna.

Moreover, the packaging carrier provided by the present disclosure can achieve miniaturization through the structural cooperation described above (e.g., the slot antenna of the outside metal layer being cooperated with the inside metal layer and the matching component), so that the antenna function can be effectively integrated in the chip package structure for saving space of the electronic device and reducing the design time of antenna.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An electronic device, comprising:
a chip package structure including:
a packaging carrier defining a thickness direction, wherein the packaging carrier includes:
an insulating layer having an inner surface and an outer surface that is opposite to the inner surface;
an outside metal layer embedded in the insulating layer and arranged adjacent to the outer surface, wherein the outside metal layer includes:
an antenna layout segment having a slot antenna recessed from an edge thereof along a first direction perpendicular to the thickness direction, wherein the slot antenna has a slot opening arranged on the edge, a bottom wall arranged away from the slot opening, and two lateral walls that are connected to the bottom wall, and wherein the antenna layout segment has a plurality of layout holes that are respectively located at two opposite sides of the slot antenna; and
a plurality of frequency adjustment pads respectively arranged in the layout holes and not in contact with the antenna layout segment, wherein the frequency adjustment pads are exposed from the outer surface of the insulating layer;
wherein the antenna layout segment has a plurality of slot-shape adjustment pads that are exposed from the outer surface of the insulating layer, and wherein the slot-shape adjustment pads are arranged adjacent to the bottom wall and are respectively located at the two opposite sides of the slot antenna; and
an inside metal layer embedded in the insulating layer and arranged adjacent to the inner surface of the insulating layer;
an encapsulant formed on the inner surface of the insulating layer; and
an electronic chip embedded in the encapsulant; and
a circuit board configured to selectively provide at least one adjustment circuit, wherein, when the chip package structure is soldered onto the circuit board, the circuit board enables two of the slot-shape adjustment pads or two of the frequency adjustment pads to be electrically coupled to each other through the at least one adjustment circuit that is arranged across the slot antenna.

2. The electronic device according to claim 1, wherein a quantity of the at least one adjustment circuit provided by the circuit board is more than one, and wherein one of the adjustment circuits connects the two of the slot-shape adjustment pads and is defined as a slot-shape adjustment circuit, and another one of the adjustment circuits connects the two of the frequency adjustment pads and is defined as a frequency adjustment circuit.

3. The electronic device according to claim 2, wherein the slot-shape adjustment pads include a plurality of first slot-shape adjustment pads that are located at one of the two opposite sides of the slot antenna and a plurality of second slot-shape adjustment pads that are located at another one of the two opposite sides of the slot antenna, and wherein each of the first slot-shape adjustment pads is allowed to be electrically coupled to any one of the second slot-shape adjustment pads through the slot-shape adjustment circuit.

4. The electronic device according to claim 3, wherein each of the first slot-shape adjustment pads faces toward one of the second slot-shape adjustment pads along a second direction that is perpendicular to the thickness direction and the first direction, and wherein the slot-shape adjustment circuit is parallel to the second direction.

5. The electronic device according to claim 2, wherein the frequency adjustment pads include a plurality of first frequency adjustment pads that are located at one of the two opposite sides of the slot antenna and a plurality of second frequency adjustment pads that are located at another one of the two opposite sides of the slot antenna, and wherein each of the first frequency adjustment pads is allowed to be electrically coupled to any one of the second frequency adjustment pads through the frequency adjustment circuit.

6. The electronic device according to claim 5, wherein each of the first frequency adjustment pads faces toward one of the second frequency adjustment pads along a second direction that is perpendicular to the thickness direction and the first direction, and wherein the frequency adjustment circuit is parallel to the second direction.

7. The electronic device according to claim 1, wherein the slot antenna has a slot depth along the first direction, and the slot-shape adjustment pads and the bottom wall have a maximum separation distance therebetween that is less than or equal to 30% of the slot depth.

8. The electronic device according to claim 1, wherein the slot antenna has a slot depth along the first direction, and the frequency adjustment pads and the slot opening have an arrangement distance therebetween that is greater than or equal to 30% of the slot depth.

9. The electronic device according to claim 1, wherein the layout holes are respectively recessed in the two lateral walls of the slot antenna.

10. The electronic device according to claim 1, wherein an inner region surrounded by the slot antenna defines an extension space along the thickness direction, and the inside metal layer includes a feeding circuit arranged across the extension space and a metal pad that is located at one side of the extending space, and wherein the chip package structure includes a matching component that is connected to the feeding circuit and the metal pad and that is embedded in the encapsulant.

11. The electronic device according to claim 10, wherein the inside metal layer includes two coupling segments electrically coupled to the antenna layout segment, and wherein the two coupling segments are respectively overlapped with the frequency adjustment pads along the thickness direction.

12. The electronic device according to claim 1, wherein the outside metal layer has a plurality of grounding pads exposed from the outer surface of the insulating layer, and the circuit board includes a grounding layer electrically coupled to the grounding pads, wherein the grounding layer has a clearance hole, and the grounding pads are arranged outside of the clearance hole, wherein a projection region defined by orthogonally projecting the slot antenna onto the grounding layer along the thickness direction is located in the clearance hole, and wherein the at least one adjustment circuit is arranged in the clearance hole and is not in contact with the grounding layer.

13. The electronic device according to claim 1, wherein the packaging carrier includes at least one expansion metal layer that is embedded in the insulating layer and that is arranged between the inside metal layer and the outside metal layer, wherein the at least one expansion metal layer has a coupling slot, and wherein at least 80% of an inner wall of the coupling slot is overlapped with the bottom wall and the two lateral walls of the slot antenna along the thickness direction.

14. The electronic device according to claim 13, wherein the at least one expansion metal layer shields the layout holes and the frequency adjustment pads along the thickness direction.

15. The electronic device according to claim 1, wherein the electronic device defines a predetermined center frequency, and the slot antenna of the chip package structure has an initial center frequency, and wherein the initial center frequency of the chip package structure is able to be adjusted to the predetermined center frequency by being connected to the at least one adjustment circuit.

16. A chip package structure, comprising:
a packaging carrier defining a thickness direction, wherein the packaging carrier includes:
an insulating layer having an inner surface and an outer surface that is opposite to the inner surface;
an outside metal layer embedded in the insulating layer and arranged adjacent to the outer surface, wherein the outside metal layer includes:
an antenna layout segment having a slot antenna recessed from an edge thereof along a first direction perpendicular to the thickness direction, wherein the slot antenna has a slot opening arranged on the edge, a bottom wall arranged away from the slot opening, and two lateral walls that are connected to the bottom wall, and wherein the antenna layout segment has a plurality of layout holes that are respectively located at two opposite sides of the slot antenna; and
a plurality of frequency adjustment pads respectively arranged in the layout holes and not in contact with the antenna layout segment, wherein the frequency adjustment pads are exposed from the outer surface of the insulating layer;
wherein the antenna layout segment has a plurality of slot-shape adjustment pads that are exposed from the outer surface of the insulating layer, and wherein the slot-shape adjustment pads are arranged adjacent to the bottom wall and are respectively located at the two opposite sides of the slot antenna; and
an inside metal layer embedded in the insulating layer and arranged adjacent to the inner surface of the insulating layer;
an encapsulant formed on the inner surface of the insulating layer; and
an electronic chip embedded in the encapsulant.

17. The chip package structure according to claim 16, wherein the slot antenna has a slot depth along the first direction, and the slot-shape adjustment pads and the bottom wall have a maximum separation distance therebetween that is less than or equal to 30% of the slot depth, and wherein the frequency adjustment pads and the slot opening have an arrangement distance therebetween that is greater than or equal to 30% of the slot depth.

18. The chip package structure according to claim 16, wherein the packaging carrier includes at least one expansion metal layer that is embedded in the insulating layer and that is arranged between the inside metal layer and the outside metal layer, wherein the at least one expansion metal layer has a coupling slot, and wherein at least 80% of an inner wall of the coupling slot is overlapped with the bottom wall and the two lateral walls of the slot antenna along the thickness direction.

19. The chip package structure according to claim 18, wherein the at least one expansion metal layer shields the layout holes and the frequency adjustment pads along the thickness direction.

20. A packaging carrier of a chip package structure, comprising:
an insulating layer having an inner surface and an outer surface that is opposite to the inner surface along a thickness direction;
an outside metal layer embedded in the insulating layer and arranged adjacent to the outer surface, wherein the outside metal layer includes:
an antenna layout segment having a slot antenna recessed from an edge thereof along a first direction perpendicular to the thickness direction, wherein the slot antenna has a slot opening arranged on the edge, a bottom wall arranged away from the slot opening, and two lateral walls that are connected to the bottom wall, and wherein the antenna layout segment has a plurality of layout holes that are respectively located at two opposite sides of the slot antenna; and
a plurality of frequency adjustment pads respectively arranged in the layout holes and not in contact with the antenna layout segment, wherein the frequency adjustment pads are exposed from the outer surface of the insulating layer;
wherein the antenna layout segment has a plurality of slot-shape adjustment pads that are exposed from the outer surface of the insulating layer, and wherein the slot-shape adjustment pads are arranged adjacent to the bottom wall and are respectively located at the two opposite sides of the slot antenna; and
an inside metal layer embedded in the insulating layer and arranged adjacent to the inner surface of the insulating layer.
